(19) United States
(12) Patent Application Publication
(10) Pub. No.: US 2010/0269878 A1
(43) Pub. Date: Oct. 28, 2010

(54) INTERNAL COMBUSTION ENGINE WITH THERMOELECTRIC GENERATOR

(75) Inventor: Kai Sebastian Kuhlbach, Bergisch Gladbach (DE)

Correspondence Address: BROOKS KUSHMAN P.C./FGTL, 1000 TOWN CENTER, 22ND FLOOR, SOUTHFIELD, MI, 48075-1238, US

(73) Assignee: FORD GLOBAL TECHNOLOGIES, LLC, Dearborn, MI (US)

(21) Appl. No.: 12/766,001

(22) Filed: Apr. 23, 2010

(30) Foreign Application Priority Data
Apr. 23, 2009 (DE) 10 2009 002 596.0

(51) Int. Cl. H01L 35/34; F01N 5/02; H01L 35/30; F02F 1/40

(52) U.S. Cl. 136/201; 60/320; 136/205; 123/41.82 R

(57) ABSTRACT

A cylinder head has at least two exhaust gas ducts, an exhaust gas collector collecting exhaust gas from the exhaust gas ducts, a coolant channel around the exhaust gas ducts and the exhaust gas collector, and a thermoelectric element in thermal contact with the exhaust gas duct, the exhaust gas collector, and the coolant channel. The thermoelectric element is arranged around the periphery of the exhaust gas duct and the exhaust gas collector.

### CROSS-REFERENCE TO RELATED APPLICATIONS

This application claims foreign priority benefits under 35 U.S.C. §119-(a)-(d) to DE 10 2009 002 596.0, filed Apr. 23, 2009, which is hereby incorporated by reference in its entirety.

### BACKGROUND

1. Technical Field

The disclosure pertains to an internal combustion engine having one or more thermoelectric generators which generate electric current due to the temperature difference between the exhaust gas of the internal combustion engine and a coolant.

2. Background Art

An internal combustion engine having a thermoelectric generator in the exhaust system is known, for example, from DE 100 41 955 A1. In this disclosure the temperature difference between the exhaust gas and the environment is used to generate electric current by means of a thermoelectric element using the Seebeck effect. The thermoelectric element may be formed along the entire length of the exhaust pipe or sections thereof. With a thermoelectric element of this type the inverse Seebeck effect, the Peltier effect, can also be used to heat components of the internal combustion engine.

US 2003/0223919 A1 discloses cooling of a thermoelectric generator arranged in an oxidation catalytic converter of an internal combustion engine by means of the engine coolant liquid.

Although thermoelectric generators according to the most recent state of the art have relatively high efficiency, the known devices for energy recovery yield comparatively little electrical output from the exhaust gas heat.

### SUMMARY

A cylinder head is disclosed which has at least two exhaust gas ducts, an exhaust gas collector collecting exhaust gas from the exhaust gas ducts, a coolant channel around the exhaust gas ducts and the exhaust gas collector, and a thermoelectric element in thermal contact with the exhaust gas duct, the exhaust gas collector, and the coolant channel. The thermoelectric element is arranged around the periphery of the exhaust gas duct and the exhaust gas collector. The thermoelectric element is in thermal contact with the exhaust gas duct on a heat-supply side and is in thermal contact with the coolant channel on a heat-dissipation side. The thermoelectric element is in direct with coolant in the coolant channel in one embodiment and in contact with metal and the metal is in direct contact with coolant in the coolant channel in another embodiment. The cylinder head is configured for a multi-cylinder engine having two exhaust gas ducts for each cylinder. The exhaust gas collector collects exhaust gases from all exhaust gas ducts from all cylinders with a single exit from the exhaust gas collector. The thermoelectric elements are arranged around the periphery of all exhaust gas ducts. The cylinder head is disposed in a vehicle and electricity generated in the thermoelectric elements supplants at least part of current supply to the vehicle. The thermoelectric element is operated as a heater by applying current to the thermoelectric element. The exhaust gas collector is integral to the cylinder head in one embodiment. In another embodiment the exhaust gas collector is a separate part from the cylinder head portion having the exhaust ducts.

A method to operate a thermoelectric generator, which is provided in a cylinder head having multiple exhaust ducts coupled to an exhaust gas collector is disclosed. The thermoelectric generator is arranged around a periphery of the exhaust ducts and the exhaust gas collector. The method includes extracting electricity from the thermoelectric generator during a normal operating mode and supplying electricity from the thermoelectric generator during an engine starting mode. The second operating mode includes heating of the exhaust ducts. The extraction of electricity occurs due to the Seebeck effect driven by a temperature difference across the thermoelectric generator. The thermoelectric generator is in thermal contact with engine coolant and with engine exhaust and the temperature difference is between the engine coolant and the engine exhaust. The exhaust ducts are coupled to an exhaust gas collector and the thermoelectric generator extends to ducts associated with the exhaust gas collector.

In one embodiment, the exhaust gas ducts in the cylinder head of the internal combustion engine are configured at least partially as an exhaust gas collector which collects the exhaust gases from a plurality of cylinders already in the region of the cylinder head. Such an exhaust gas collector has an especially large surface area along which thermoelectric generators can be arranged. The output of the thermoelectric generator or generators can thereby be increased to such an extent that the conventional generator known to be present on an internal combustion engine can be dimensioned correspondingly smaller or may even be omitted completely. Thus, with the use of such an internal combustion engine in a motor vehicle, some or even all of the electric power required in the motor vehicle is generated thermoelectrically in a fuel-saving manner.

Furthermore, an exhaust gas collector integrated in the cylinder head and cooled by the engine coolant has the advantage that the exhaust gas temperature is lowered at the outlet of the cylinder head, thereby lowering the requirements for high-temperature resistance of exhaust gas lines, exhaust gas aftertreatment devices and optionally turbochargers or superchargers, attached to the cylinder head. Moreover, the engine coolant is brought up to operating temperature more quickly by the hot exhaust gases, so that the entire engine block is heated up quickly, reducing friction, and the passenger cell can also be heated quickly and powerfully.

Some thermoelectric generators, in particular thermoelectric elements, can be operated as heat pumps by means of a current supply. This feature, too, in conjunction with an exhaust gas collector integrated in the cylinder head, is especially advantageous since the exhaust gas collector can be brought rapidly up to operating temperature upon starting the engine, so that exhaust gas aftertreatment devices connected downstream also reach operating temperature more quickly.

One or more thermoelectric generators in an internal combustion engine has the further advantage that it is especially space-saving. In particular, an exhaust gas aftertreatment device, such as an oxidation catalytic converter or a turbocharger, can follow directly after the section in which thermoelectric energy is acquired. The exhaust gas line section in which thermoelectric energy is acquired can therefore replace the otherwise usual pipe connection between cylinder head and exhaust gas aftertreatment device or turbocharger.

### BRIEF DESCRIPTION OF THE DRAWINGS

The disclosure is explained in more detail below in reference to the drawings, in which:

FIGS. 1 and 2 are schematic cross sections of a four-valve four-cylinder engine having a thermoelectric generator according to embodiments of the disclosure.

### DETAILED DESCRIPTION

As those of ordinary skill in the art will understand, various features of the embodiments illustrated and described with reference to any one of the Figures may be combined with features illustrated in one or more other Figures to produce alternative embodiments that are not explicitly illustrated or described. The combinations of features illustrated provide representative embodiments for typical applications. However, various combinations and modifications of the features consistent with the teachings of the present disclosure may be desired for particular applications or implementations. Those of ordinary skill in the art may recognize similar applications or implementations whether or not explicitly described or illustrated.

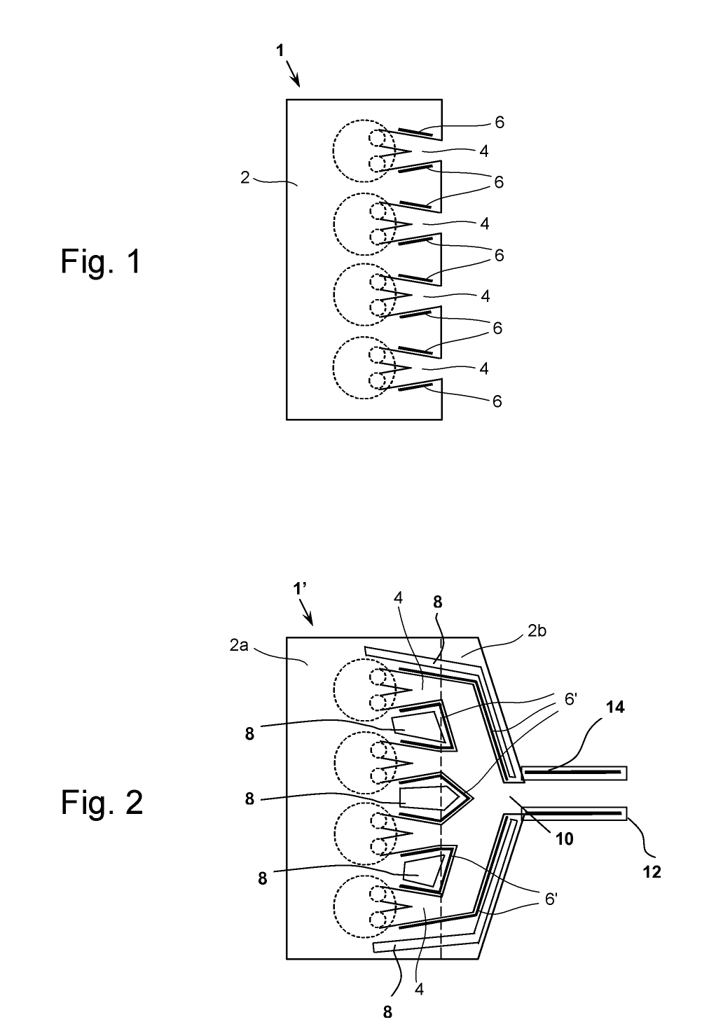

In FIG. 1, a cylinder head 2 two for a four-cylinder engine 1 has two exhaust valve openings per cylinder. From the top view in FIG. 1, the rest of the engine is not visible. At the exhaust valve openings of each cylinder are exhaust ducts 4 which converge in a V-formation. The V-formations each open separately at the edge of cylinder head 2 into an exhaust manifold (not shown) coupled to cylinder head 2.

Arranged around the periphery of exhaust gas ducts 4 are thermoelectric elements 6, which are in thermal contact on the heat-supply side with the exhaust gas flowing through exhaust gas ducts and in thermal contact on the heat-dissipation side with liquid coolant which flows through coolant channels (not shown) in cylinder head 2. Between thermoelectric elements 6 and the exhaust gas and coolant there is direct thermal contact, in one embodiment. Alternatively, there is indirect thermal contact, for example, via the metal of cylinder head 2.

In the embodiment shown in FIG. 2, the cylinder head consists of two sections: a cylinder part 2a and an exhaust gas collector part 2b. In FIG. 2, a broken straight line shows the boundary between the cylinder part 2a and the exhaust gas collector part 2b. Alternatively, cylinder part 2a and exhaust gas collector part 2b may be a one-piece element. Or, in yet another alternative, the exhaust gas collector part 2b may be bolted to the cylinder part 2a with coolant flowing through the interface between the two parts.

In the embodiment of FIG. 2, as in the embodiment of FIG. 1, exhaust gas ducts 4, which first converge in a V-formation, begin at the exhaust valve openings of each cylinder. The exhaust gas ducts 4 are then brought together in exhaust gas collector part 2b to form a common outlet opening 10. Coolant ducts 8 are provided at least around exhaust gas ducts 4 and exhaust gas collector part 2b. Coolant ducts 8 are shown as discreet units; however, they are commonly connected, but such connections are not shown in cross-sectional view. In the embodiment in FIG. 2, thermoelectric elements 6′ are shown just below the surface of exhaust ducts 4. Depending on the temperature characteristics of cylinder head 1′ and the specification limits of thermoelectric elements 6′ in regards to high temperature, thermoelectric elements 6′ may be placed closer to walls of coolant ducts 8. In another alternative, thermoelectric elements 6′ may be placed within coolant ducts 8. In FIG. 2, the duct walls are drawn in a simple angular manner; in reality, of course, they are rounded to allow flow with little restriction.

Unlike a conventional exhaust gas collector exposed to the air, the exhaust gas collector part 2b is liquid-cooled, namely by the coolant of the internal combustion engine 1′ which flows through coolant channels 8 in the cylinder part 2a and/or in the exhaust gas collector part 2b. In one embodiment, the cooling occurs directly such that the exhaust gas collector part 2b contains coolant channels. Alternatively, the exhaust gas collector part 2b is made of metal and is in good thermal contact with the liquid-cooled cylinder part 2a.

As in the embodiment of FIG. 1, thermoelectric elements 6′ of FIG. 2 are drawn with thicker lines. Thermoelectric elements 6′ are arranged around the periphery of exhaust gas ducts 4. Thermoelectric elements 6′ additionally extend along the internal walls of the exhaust gas collector part 2b. It can be seen that the area available for thermoelectric conversion in the embodiment of FIG. 2 is much greater than in the embodiment of FIG. 1.

Also shown in FIG. 2 is an exhaust gas pipe 12 coupled to cylinder head 1′ for conducting gases out of cylinder head 1′ to a turbine and/or exhaust aftertreatment devices (not shown). Such exhaust gas pipe 12, which is external to cylinder head 1′, is also provided thermoelectric elements 14 arranged around exhaust gas pipe 12.

An exhaust gas aftertreatment device, such as an oxidation catalytic converter (not shown), or a boosting device such as a turbocharger or supercharger (not shown), may be connected directly to the outlet opening of exhaust collector part 2b.

FIG. 2 shows exhaust gas collector part 2b as lying in a plane with the cylinder part 2a. However, exhaust gas collector part 2b may also be curved, for example such that the outlet opening is oriented in the direction of the cylinder axis and towards the crankcase of the internal combustion engine. As a result, the exhaust gas aftertreatment device or boosting device connected to the outlet opening can be accommodated in an especially space-saving manner directly next to the cylinder block.

While the best mode has been described in detail with respect to particular embodiments, those familiar with the art will recognize various alternative designs and embodiments within the scope of the following claims. While various embodiments may have been described as providing advantages or being preferred over other embodiments with respect to one or more desired characteristics, as one skilled in the art is aware, one or more characteristics may be compromised to achieve desired system attributes, which depend on the specific application and implementation. These attributes include, but are not limited to: cost, strength, durability, life cycle cost, marketability, appearance, packaging, size, serviceability, weight, manufacturability, ease of assembly, etc. The embodiments described herein that are characterized as less desirable than other embodiments or prior art implementations with respect to one or more characteristics are not outside the scope of the disclosure and may be desirable for particular applications.

What is claimed:

1. A cylinder head, comprising:
at least two exhaust gas ducts;
an exhaust gas collector collecting exhaust gas from the exhaust gas ducts;
a coolant channel around the exhaust gas ducts and the exhaust gas collector; and
a thermoelectric element in thermal contact with the exhaust gas duct, the exhaust gas collector, and the coolant channel wherein the thermoelectric element is arranged around the periphery of the exhaust gas duct and the exhaust gas collector.

2. The cylinder head of claim 1 wherein the thermoelectric element is in thermal contact with the exhaust gas duct wall on a heat-supply side and is in thermal contact or in partial contact with the coolant channel on a heat-dissipation side.

3. The cylinder head of claim 1 wherein the thermoelectric element is in direct contact with coolant in the coolant channel.

4. The cylinder head of claim 1 wherein the thermoelectric element is in contact with metal and the metal is in direct contact with coolant in the coolant channel.

5. The cylinder head of claim 1 wherein the cylinder head is configured for a multi-cylinder engine, the cylinder head has two exhaust gas ducts for each cylinder, and the exhaust gas collector collects exhaust gases from all exhaust gas ducts from all cylinders with a single exit from the exhaust gas collector, the cylinder head further comprising:
an exhaust pipe coupled to the exhaust gas collector, the exhaust pipe having thermoelectric elements.

6. The cylinder head of claim 1 wherein thermoelectric elements are arranged around the periphery of all exhaust gas ducts.

7. The cylinder head of claim 6 wherein the cylinder head is disposed in a vehicle and electricity generated in the thermoelectric elements supplants at least part of current supply to the vehicle.

8. The cylinder head of claim 1 wherein the thermoelectric element is operated as a heater by applying current to the thermoelectric element.

9. The cylinder head of claim 1 wherein the exhaust gas collector is integral to the cylinder head.

10. The cylinder head of claim 1 wherein the exhaust gas collector comprises a separate part from the cylinder head portion having the exhaust ducts.

11. A method to operate a thermoelectric generator wherein the thermoelectric generator is provided in a cylinder head having multiple exhaust ducts coupled to an exhaust gas collector, the thermoelectric generator being arranged around a periphery of the exhaust ducts and the exhaust gas collector, the method comprising:
extracting electricity from the thermoelectric generator during a normal operating mode; and
supplying electricity from the thermoelectric generator during an engine starting mode.

12. The method of claim 11 wherein the second operating mode comprises heating of the exhaust ducts.

13. The method of claim 11 wherein the extracting electricity occurs due to the Seebeck effect driven by a temperature difference across the thermoelectric generator.

14. The method of claim 11 wherein the thermoelectric generator is in thermal contact with engine coolant and with engine exhaust and the temperature difference is between the engine coolant and the engine exhaust.

15. The method of claim 11 wherein the exhaust ducts are coupled to an exhaust gas collector and the thermoelectric generator extends to ducts associated with the exhaust gas collector.

16. An internal combustion engine, comprising:
a cylinder head having at least two exhaust gas ducts;
an exhaust gas collector coupled to the cylinder head and collecting exhaust gas from the exhaust gas ducts;
a coolant channel disposed in the cylinder head; and
a thermoelectric element in thermal contact with the exhaust gas collector and the coolant channel wherein the thermoelectric element is arranged around the periphery of the exhaust gas collector.

17. The internal combustion engine of claim 16 wherein the thermoelectric element is further arranged around the periphery of the exhaust gas ducts, the engine further comprising:
an exhaust pipe coupled downstream of the exhaust gas collector, the exhaust pipe having a thermoelectric element arranged peripherally around the exhaust pipe.

18. The internal combustion engine of claim 16 wherein the thermoelectric element is supplied current to heat the exhaust ducts and the exhaust gas collector during starting.

19. The internal combustion engine of claim 17 wherein electricity is generated in the thermoelectric element when the thermoelectric element is in thermal contact with exhaust ducts and the exhaust gas collector and in thermal contact with the coolant duct at a temperature significantly lower than a temperature of the exhaust gas ducts and the exhaust gas collector.

20. The internal combustion engine of claim 16 wherein the thermal contact between the thermoelectric element and engine coolant is indirect with metal being the heat transfer medium between the two.
